(19) United States
(12) Patent Application Publication
(10) Pub. No.: US 2012/0009398 A1
(43) Pub. Date: Jan. 12, 2012

(54) HOUSING AND METHOD FOR MANUFACTURING HOUSING

(75) Inventors: HSIN-PEI CHANG, Tu-Cheng (TW); WEN-RONG CHEN, Tu-Cheng (TW); HUAN-WU CHIANG, Tu-Cheng (TW); CHENG-SHI CHEN, Tu-Cheng (TW); MAN-XI ZHANG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 12/968,406

(22) Filed: Dec. 15, 2010

(30) Foreign Application Priority Data
Jul. 12, 2010 (CN) 201010223943.2

(51) Int. Cl. B32B 15/04; C23C 14/06; C23C 14/35

(52) U.S. Cl. 428/213; 428/457; 428/447; 428/336; 428/698; 204/192.15

(57) ABSTRACT

A housing includes a substrate; a corrosion resistance layer deposited on the substrate; a bonding layer deposited on the corrosion resistance layer; and an abrasion resistance layer deposited on the bonding layer

### CROSS-REFERENCE TO RELATED APPLICATIONS

The present application is related to co-pending U.S. patent applications (Attorney Docket No.US34387, US34392), entitled “HOUSING AND METHOD FOR MANUFACTURING HOUSING”, by Zhang et al. These applications have the same assignee as the present application and have been concurrently filed herewith. The above-identified applications are incorporated herein by reference.

### BACKGROUND

1. Technical Field

The exemplary disclosure generally relates to housings and method for manufacturing the housings.

2. Description of Related Art

With the development of wireless communication and information processing technology, portable electronic devices, such as mobile telephones and electronic notebooks are now in widespread use. Magnesium and magnesium alloys have good heat dissipation and can effectively shield electromagnetic interference. Therefore. magnesium and magnesium alloys are widely used to manufacture housings of portable electronic devices. However, magnesium and magnesium alloys have a lower corrosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a housing.

FIG. 2 is a diagram of manufacturing the housing in FIG. 1.

FIG. 3 is a schematic view of a magnetron sputtering coating machine for manufacturing the housing in FIG. 1.

### DETAILED DESCRIPTION

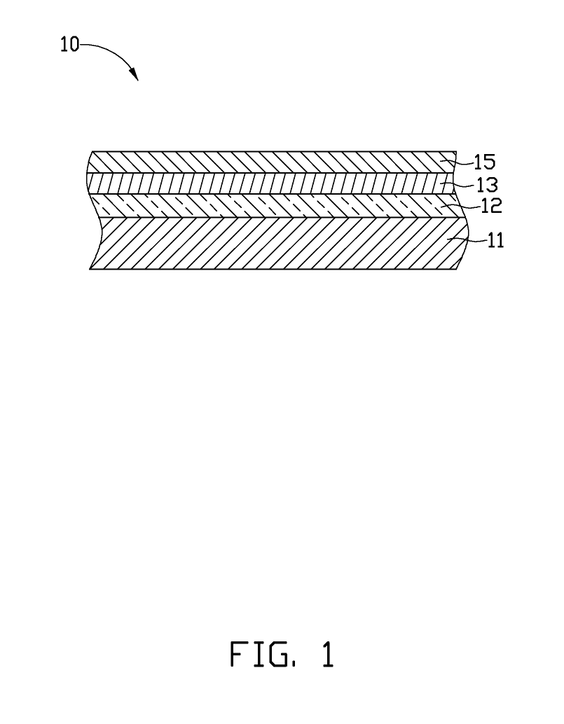

Referring to FIG. 1, an exemplary housing 10 includes a substrate 11, a corrosion resistance layer 12 deposited on the substrate 11, a bonding layer 13 deposited on the corrosion resistance layer 12 and an abrasion resistance layer 15 deposited on the bonding layer 13. The substrate 11 may be made of magnesium or magnesium alloy. The corrosion resistance layer 12 is comprised of silane which has a chemical formula SiH4. The corrosion resistance layer 12 has a thickness ranging from about 0.5 micrometer to about 3 micrometer.

The bonding layer 13 improves the binding force between the corrosion resistance layer 12 and the abrasion resistance layer 15. In this embodiment, the bonding layer 13 is made of aluminum. The abrasion resistance layer 15 may be titanium carbonitride (TiCN) layer. A total thickness of the corrosion resistance layer 12 and the bonding layer 13 is about 2 micrometer to about 6 micrometer. In another exemplary embodiment, the bonding layer 13 is made of Titanium. The abrasion resistance layer 15 may be titanium carbonitride (TiCN) layer, aluminum nitride (AlN) layer, titanium nitride (TiN) layer, chromium nitride (CrN) layer.

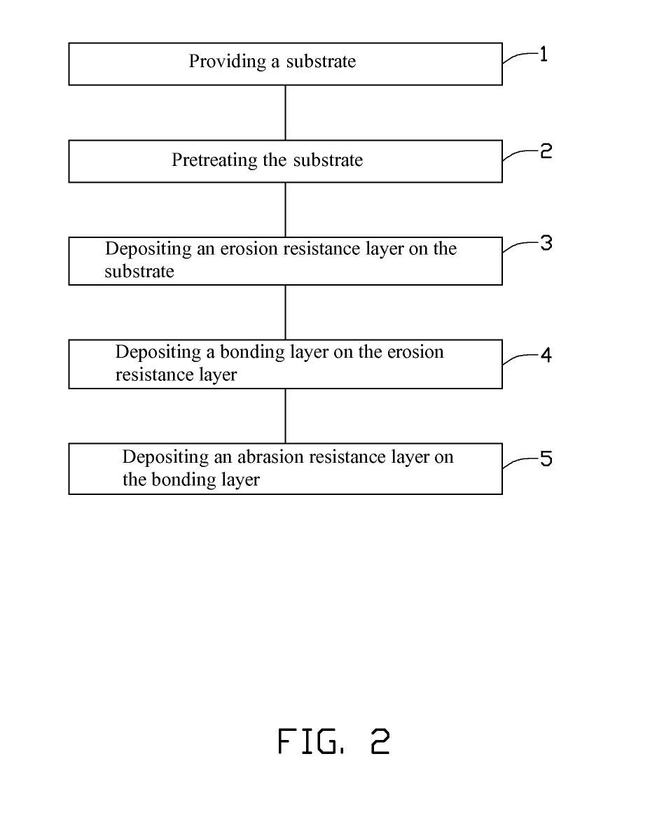

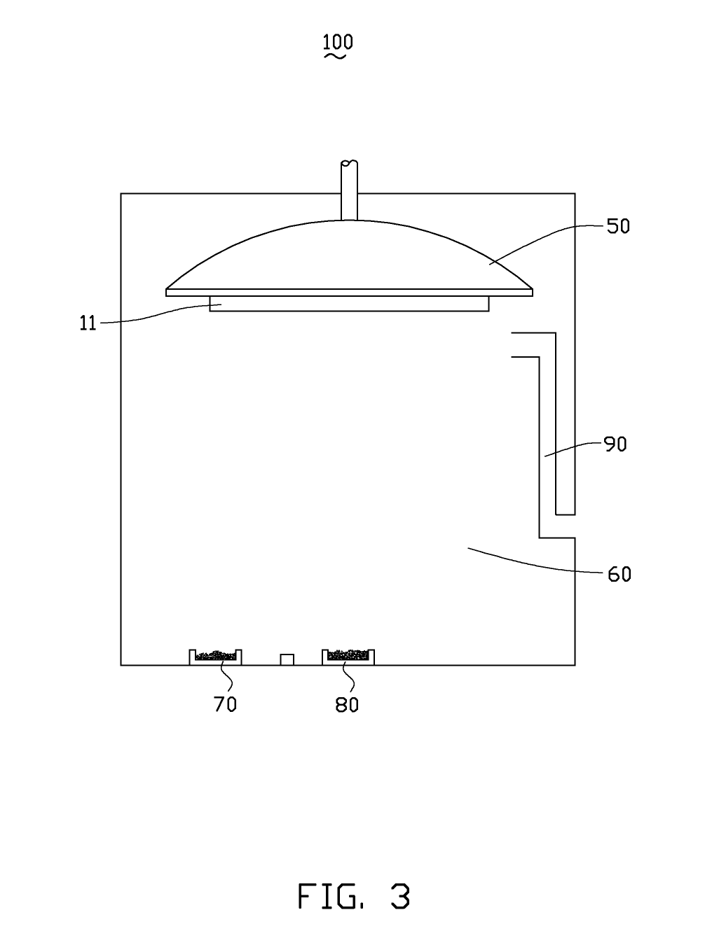

Referring to FIGS. 2 and 3, a method for manufacturing the housing 10 includes the following steps.

A substrate 11 is provided. The substrate 11 may be made of magnesium or magnesium alloy.

The substrate 11 is pretreated. First, the substrate 11 is polished and electrolyzed to make the surface of the substrate 11 shine. The substrate 11 is then dipped into an oil removing solution having a temperature of from 60 centigrade to 80 centigrade for about 30 seconds to 60 seconds to remove grease. The oil removing solution is a water solution containing 25˜30 g/L Na2CO3, 20˜25 g/L Na3PO4 12H2O and 1˜3 g/L neopelex. After the oil removing step, the substrate 11 is taken out and then washed with a pure water. Second, the substrate 11 is dipped into an acid solution comprised of 0.5˜3 wt % HNO for a time of about 20 to about 50 seconds at room temperature to remove oxides and/or impurities. The substrate 11 is then washed with pure water. Third, the substrate 11 is dipped into an alkaline solution to neutralize acid solution on the magnesium or magnesium alloy at a temperature of 40 to 50 for a time of 3 seconds to 5 seconds to further remove oxides, thus improving adhesion between the substrate and the corrosion resistance layer 12. The alkaline solution comprises 40-70 g/L NaOH, 10-20 g/L Na3PO4 12H2O, 25-30 g/L Na2CO3, and 40-50 g/L AEO-9 (Fatty alcohol ethoxylates) After Alkaline washing, the substrate 11 is then washed with pure water. Last, the substrate 11 is dried.

The corrosion resistance layer 12 is deposited on the substrate 11 by a spraying process, spread coating process or dipping coating process. The corrosion resistance layer 12 is comprised of silicane. In this exemplary embodiment, a spraying process deposits the corrosion resistance layer 12. First, the substrate 11 is dipped into a primer coating solution containing 25-30 g/L prime coat(e.g., sold under the Dow Corning® 1205), at a room temperature for about 30 seconds to about 60 seconds. After that, the substrate 11 is taken out and then is dried, to deposit a corrosion resistance layer 12 on the substrate 11. The corrosion resistance layer 12 is comprised of silane, and the silane has a good waterproof, corrosion resistance and a strong binding force to the substrate 11. Thus, the corrosion resistance layer 12 enhances the corrosion resistance of the housing 10. The primer coating solution in the spraying process may be Dow Corning® 9801 prime coat or Dow Corning® 1200 prime coat.

The bonding layer 13 is deposited on the corrosion resistance layer 12. The substrate 11 is retained on a rotatable bracket 50 in a vacuum chamber 60 of a magnetron sputtering coating machine 100. The temperature of the vacuum chamber 60 is adjusted to 50˜150. The vacuum level of the vacuum chamber 60 is adjusted to 8.0×10-3˜5.0×10-2 Pa. Pure argon is floated into the vacuum chamber 60 at a flux of about 150 sccm (Standard Cubic Centimeters per Minute) from a gas inlet 90. A bias voltage applied to the substrate 11 in a range from −50 to −300 volts; an aluminum target 70 is evaporated for a time of about 100 seconds to about 1800 seconds, to deposit the bonding layer 13 on the erosion layer 12.

The abrasion resistance layer 15 is deposited on the bonding layer 13. Pure argon is floated into the vacuum chamber 60 at a flux of about 60 sccm to 80 sccm and acetylene is floated into the vacuum chamber at a flux of about 70 sccm to 90 sccm from the gas inlet 90. A bias voltage applied to the substrate 11 in a range from −50 to −300 volts; a titanium target 80 is evaporated for a time of about 120 seconds to about 3000 seconds, to deposit the abrasion resistance layer 15 on the bonding layer 13.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate;
a corrosion resistance layer deposited on the substrate;
a bonding layer deposited on the corrosion resistance layer; and
an abrasion resistance layer deposited on the bonding layer.

2. The housing as claimed in claim 1, wherein the substrate is made of magnesium or magnesium alloy.

3. The housing as claimed in claim 1, wherein the corrosion resistance layer is comprised of silicane.

4. The housing as claimed in claim 1, wherein the corrosion resistance layer has a thickness ranging from about 0.5 micrometer to about 3 micrometer.

5. The housing as claimed in claim 1, wherein bonding layer is for improving the adhesion between the corrosion resistance layer and the abrasion resistance layer.

6. The housing as claimed in claim 1, wherein the bonding layer is made of aluminum or titanium.

7. The housing as claimed in claim 1, wherein the abrasion resistance layer is a titanium carbonitride layer.

8. The housing as claimed in claim 1, wherein the corrosion resistance layer and the bonding layer have a thickness ranging from about 2 micrometer to about 6 micrometer.

9. The housing as claimed in claim 1, wherein the abrasion resistance layer is an aluminum nitride layer.

10. The housing as claimed in claim 1, wherein the abrasion resistance layer is a titanium nitride layer.

11. The housing as claimed in claim 1, wherein the abrasion resistance layer is a chromium nitride layer.

12. A method for manufacturing an housing comprises steps of:
providing a magnesium or magnesium alloy substrate;
depositing a silicane corrosion resistance layer on the substrate;
depositing an aluminum or titanium bonding layer on the corrosion resistance layer; and
depositing a titanium carbonitride layer abrasion resistance layer on the bonding layer.

13. The method of claim 12, wherein during depositing the bonding layer on the corrosion resistance layer, the substrate is retained in a vacuum chamber of a magnetron sputtering coating machine, the temperature of the vacuum chamber is adjusted to 50˜150° C.; the vacuum level of the vacuum chamber is adjusted to 8.0×10-3˜5.0×10-2 Pa; pure argon is floated into the vacuum chamber at a flux of about 150 sccm; a bias voltage applied to the substrate in a range from −50 to −300 volts; an aluminum target is evaporated for a time of about 100 second to about 1800 second, to deposit the bonding layer on the corrosion resistance layer.

14. The method of claim 13, wherein during depositing the abrasion resistance layer on the bonding layer, pure argon is floated into the vacuum chamber at a flux of about 60 sccm to 80 sccm and an acetylene is floated into the vacuum chamber at a flux of about 70 sccm to 90 sccm; a bias voltage applied to the substrate in a range from −50 to −300 volts; a titanium target is evaporated for a time of about 120 second to about 3000 second, to deposit the abrasion resistance layer on the bonding layer.

15. The method of claim 12, wherein further including a step of pretreating the substrate between providing the substrate and depositing the corrosion resistance layer on the substrate, the step of pretreating the substrate includes a first step which the substrate is polished and electrolyzed to make the surface of the substrate shine.

16. The method of claim 15, wherein the substrate is then washed with a water containing 25˜30 g/L Na2CO3, 20˜25 g/L Na3PO4 12H2O and 1˜3 g/L neopelex after the substrate the substrate is polished and electrolyzed.

17. The method of claim 16, wherein the step of pretreating the substrate further includes a second step which the substrate is washed with an acid solution comprised of 0.5˜3 wt % HNO for a time of 20 to 50 seconds, to remove oxides and/or impurities.

18. The method of claim 17, wherein the step of pretreating the substrate further includes a third step which the substrate is washed by an alkaline solution with a temperature of 40 to 50 for a time of 3 to 5 seconds, to further remove oxides

19. The method of claim 18, wherein the alkaline solution is a water comprised of 40-70 g/L NaOH, 10-20 g/L Na3PO4 12H2O, 25˜30 g/L Na2CO3, and 40-50 g/L AEO-9.
